(19) United States
(12) Patent Application Publication
(10) Pub. No.: US 2008/0297207 A1
(43) Pub. Date: Dec. 4, 2008

(54) DOUBLE DATA RATE TRANSMITTER AND CLOCK CONVERTER CIRCUIT THEREOF

(75) Inventors: Cheng-Yen Huang, Hsinchu (TW); Chia-Ying Wang, Taichung County (TW)

Correspondence Address: J C PATENTS, INC., 4 VENTURE, SUITE 250, IRVINE, CA, 92618, US

(73) Assignee: FARADAY TECHNOLOGY CORP., Hsinchu (TW)

(21) Appl. No.: 11/756,902

(22) Filed: Jun. 1, 2007

(51) Int. Cl. H03B 21/00; H03K 19/096; H03M 7/00

(52) U.S. Cl. 327/107; 326/93; 341/61

(57) ABSTRACT

A double data rate (DDR) transmitter and a clock converter circuit are provided. The clock converter circuit includes a first logic circuit and a second logic circuit. The first logic circuit receives a clock signal as a trigger signal, performs a sequential logic operation based on the clock signal, and outputs a result of the sequential logic operation. The second logic circuit is coupled to the first logic circuit. The second logic circuit performs a combinational logic operation based on the output of the first logic circuit and outputs a result of the combinational logic operation as a converted signal. The converted signal has the same waveform and frequency as those of the clock signal, and the phases of the clock signal and the converted signal are the same or only slightly different.

### BACKGROUND OF THE INVENTION

1. Field of the Invention

The present invention generally relates to a double data rate (DDR) transmitter, in particular, to a clock converter circuit thereof.

2. Description of Related Art

The technique of double data rate (DDR) has been broadly applied to memories. FIG. 1 is a partial circuit diagram of a conventional DDR transmitter, wherein the multiplexer 101 receives a clock signal tx_ck and selects and outputs one of two data txd1 and txd2 according to the status of the clock signal tx_ck. According to such design, a data can be respectively output at the rising edge and falling edge of the clock signal tx_ck so that DDR is achieved without a clock signal of double frequency.

DDR transmitter transmits data and a clock signal to a corresponding receiver. Certain timing conditions, such as setup time and hold time, have to be met to make sure that the receiver receives the data correctly. In other words, a specified timing correspondence between the clock signal and the data signal has to be satisfied, and such a purpose can be accomplished by designing a clock tree while an application-specific integrated circuit (ASIC) is designed.

However, an embodied circuit has to be verified in terms of production cost and efficiency before it is mass-produced, and field-programmable gate array (FPGA) is usually used for such verification. The clock tree of a FPGA is usually a prefabricated circuit which is not adjustable. Besides, it is very difficult to apply a stable timing constraint to a clock signal with an electronic design automation (EDA) software.

A solution for the problem described above is provided as the circuit illustrated in FIG. 2. FIG. 2 illustrates a circuit unit for a conventional DDR transmitter. The input terminal of the D flip-flop 201 is connected to the high voltage level of the voltage source VCC, and the input terminal of the D flit-flop 202 is grounded (GND), which is, connected to the low voltage level. The multiplexer 203 selects and outputs one of the outputs of the D flip-flop 201 and D flip-flop 202 according to the clock signal tx_ck1. The output signal tx_ck2 of the multiplexer 203 is as illustrated in FIG. 3, and which is delayed from the original clock signal tx_ck1. The circuit in FIG. 2 is mainly used for delaying a clock signal, and it may also be used for delaying a data signal by only receiving two data from the input terminals of the D flip-flop 201 and the D flip-flop 202. The circuit in FIG. 2 is a fixed cell disposed by an output pad of the chip. The clock signal and data signal can be respectively sent to such circuit units at different distances so that different delays can be generated and the specified timing correspondence can be achieved.

The circuit illustrated in FIG. 2 still has its disadvantages though it is easier for resolving foregoing problem of timing correspondence by applying timing constraint to the clock signal using such a circuit. Such a unit circuit is restricted by its position therefore is not flexible in its application. Besides, such unit circuit is native to FGPA and can be used directly; however, it is not native to ASIC and has to be designed to use. Thus, two different designs of the same DDR transmitter have to be provided respectively for FPGA and ASIC, which not only complicates the design procedure but also increases the production cost.

### SUMMARY OF THE INVENTION

Accordingly, the present invention is directed to a clock converter circuit, wherein a clock signal is converted into a general non-clock signal so that a timing constraint can be applied to the signal easily in both FPGA and ASIC, and the circuit is not restricted by the position thereof.

The present invention further provides a double data rate (DDR) transmitter using foregoing clock converter circuit, wherein the corresponding timing between a clock signal and a data signal can be adjusted easily and the circuit is not restricted by the position thereof during a FPGA verification.

The present invention provides a clock converter circuit including a first logic circuit and a second logic circuit. The first logic circuit receives a clock signal as a trigger signal, performs a sequential logic operation according to the clock signal, and output a result of the sequential logic operation. The second logic circuit is coupled to the first logic circuit, performs a combinational logic operation according to the output of the first logic circuit, and outputs a result of the combinational logic operation as a converted signal. The converted signal has the same waveform and frequency as those of the clock signal, and the phases of the two signals are the same or only slightly different.

According to an embodiment of the present invention, the clock signal enters a clock terminal of a flip-flop, and the first logic circuit performs the sequential logic operation according to the status of an output terminal of the flip-flop.

According to an embodiment of the present invention, the first logic circuit includes a first frequency divider circuit and a second frequency divider circuit. The first frequency divider circuit performs a first frequency division operation according to the clock signal and outputs a result of the first frequency division operation to the second logic circuit. The second frequency divider circuit performs a second frequency division operation according to the clock signal and outputs a result of the second frequency division operation to the second logic circuit.

According to an embodiment of the present invention, the first logic circuit includes a first frequency divider circuit and a second frequency divider circuit. The first frequency divider circuit performs a first frequency division operation according to the clock signal and outputs a result of the first frequency division operation to the second logic circuit. The second frequency divider circuit performs a second frequency division operation according to the clock signal and a result of the first frequency division operation and outputs a result of the second frequency division operation to the second logic circuit.

According to an embodiment of the present invention, the clock signal is from a clock tree.

The present invention further provides a DDR transmitter including a clock converter circuit, a first storage, a second storage, and a multiplexer. The clock converter circuit receives a clock signal as a trigger signal, performs a sequential logic operation according to the clock signal, and outputs a result of the sequential logic operation as a converted signal. The converted signal has the same waveform and frequency as those of the clock signal, and the phases of the two signals are the same or only slightly different. The first and the second storage are respectively used for storing a first and a second data. The multiplexer is coupled to the clock converter circuit, the first storage, and the second storage, and the multiplexer selects and outputs one of the first and the second data according to the converted signal.

According to an embodiment of the present invention, each of the first and the second storage includes a D flip-flop.

In the present invention, a sequential logic circuit, such as a flip-flop, is used for converting a clock signal into a general signal, so that a timing constraint can be easily applied to the clock signal regardless of FPGA or ASIC, and the circuit is not restricted by its position anymore. Accordingly, the design of the circuit is simplified and production cost thereof is reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a partial circuit diagram of a conventional double data rate (DDR) transmitter.

FIG. 2 illustrates a circuit unit for a conventional DDR transmitter.

FIG. 3 illustrates waveforms of signals in FIG. 2.

FIG. 4 is a partial circuit diagram of a DDR transmitter according to an embodiment of the present invention.

FIG. 5 illustrates waveforms of signals in FIG. 4.

FIG. 6 is a diagram of a clock converter circuit according to an embodiment of the present invention.

FIG. 7 is a partial circuit diagram of a DDR transmitter according to an embodiment of the present invention.

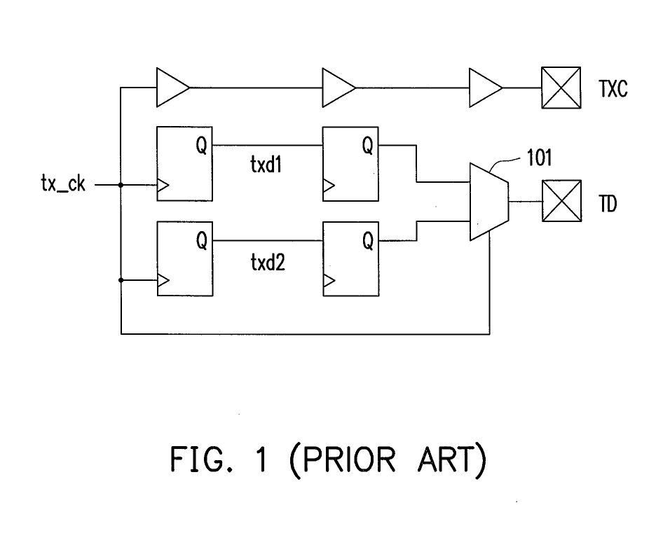

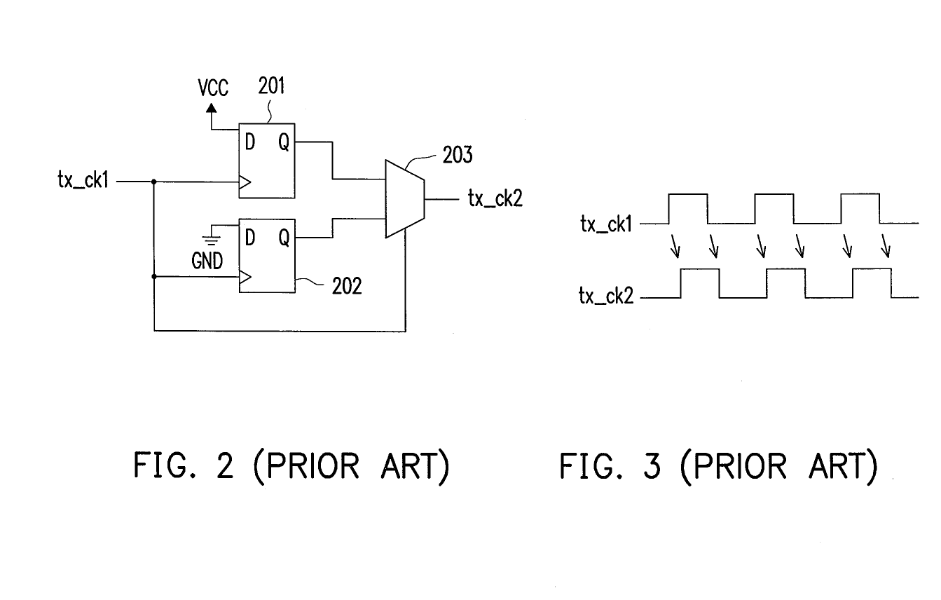

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

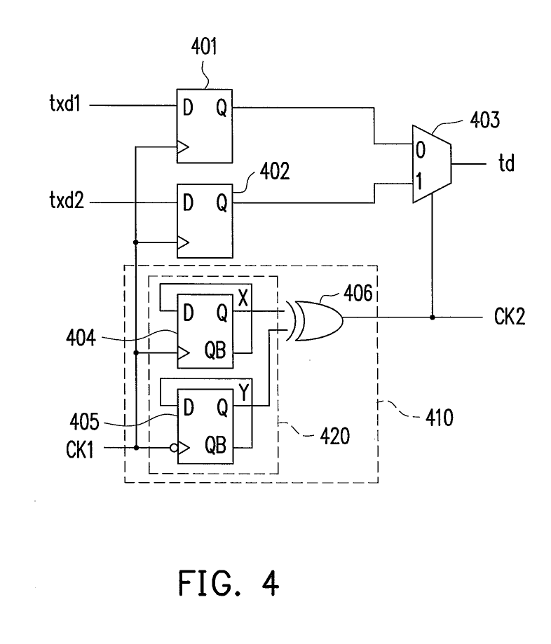

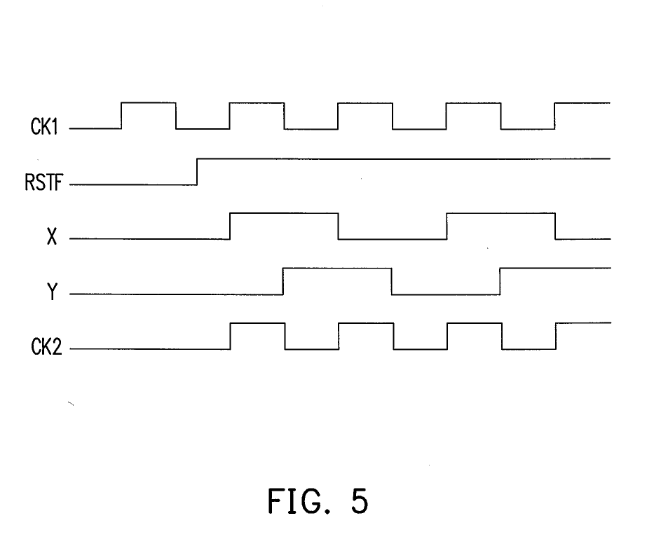

FIG. 4 is a partial circuit diagram of a DDR transmitter according to an embodiment of the present invention. The circuit illustrated in FIG. 4 includes a clock converter circuit 410, D flip-flops 401 and 402, and a multiplexer 403. The clock converter circuit is mainly used for converting an input clock signal CK1 to a general non-clock signal so that timing constraint can be applied easily. To be specific, the clock converter circuit 410 receives the clock signal CK1 as the trigger signal of the D flip-flops 404 and 405, performs a sequential logic operation according to the clock signal CK1, and outputs a result of the sequential logic operation as a converted signal CK2. The converted signal CK2 has the same waveform and frequency as those of the clock signal CK1, as illustrated in FIG. 5, and the phases of the two signals are the same or only slightly different. The converted signal CK2 is used for replacing the clock signal CK1, thus, the phase difference between the two is acceptable as long as it does not encumber the replacement. As a general signal, the converted signal CK2 can be applied with timing constraint easily to meet the specification of DDR transmitter.

The D flip-flop 401 is used for storing a data txd1 and the D flip-flop 402 is used for storing a data txd2. The multiplexer 403 is coupled to the clock converter circuit 410 and the D flip-flops 401 and 402. The multiplexer 403 selects and outputs one of the stored data signal txd1 and txd2 according to the status of the converted signal CK2 in order to achieve double data transmission rate. Since the D flip-flops 401 and 402 are used for storing data, other circuits which are capable of data storage can be used in other embodiments of the present invention.

The clock converter circuit 410 includes a logic circuit 420 and a XOR gate 406, wherein the logic circuit 420 further includes D flip-flops 404 and 405. The D flip-flop 404 is positive edge-triggered, and the D flip-flop 405 is negative edge-triggered. Each of the D flip-flops 404 and 405 has a clock terminal (denoted with a triangle), an input terminal (D), a non-inverting output terminal (Q), and a inverting output terminal (QB), wherein the clock terminal receives the clock signal CK1, the input terminal is coupled to the inverting output terminal thereof, and the non-inverting output terminal is coupled to the XOR gate 406. The XOR gate 406 receives the output signal X of the D flip-flop 404 and the output signal Y of the D flip-flop 405, performs an XOR operation, and then outputs the converted signal CK2. The waveforms of the signals CK1 and CK2 are illustrated in FIG. 5.

The clock signal CK1 is from a clock tree of the system, and the circuit in FIG. 4 is connected to the end of the clock tree. The D flip-flops 404 and 405 divide the frequency of the clock signal CK1 and output it as signals X and Y. Since the output signals X and Y have turned into general non-clock signals, a timing constraint can be easily applied thereto by an EDA software regardless of ASIC or FPGA. The XOR gate 406 is used for restoring the waveform of the clock signal CK1 based on the signals X and Y.

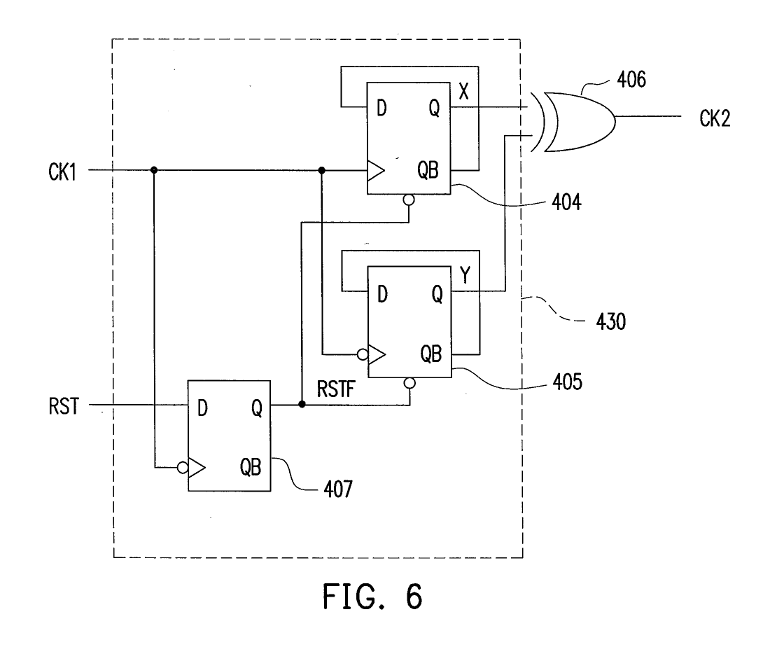

FIG. 4 does not show the reset terminals of the D flip-flops. As shown in FIG. 5, the reset signal of the D flip-flops 404 and 405 has to be enabled when the clock signal CK1 is at its low status to ensure that the waveform of the converted signal CK2 is correct, wherein RSTF is the reset signal of the D flip-flops 404 and 405. The design illustrated in FIG. 6 may be adopted in order to make sure that the reset signal RSTF is enabled at the right time.

FIG. 6 is a diagram of a clock converter circuit according to another embodiment of the present invention. Referring to FIG. 6, the clock converter circuit includes a logic circuit 430 and a XOR gate 406, wherein the logic circuit 430 further includes D flip-flops 404, 405, and 407. The difference between the clock converter circuits in FIG. 6 and FIG. 4 is that a D flip-flop 407 is added to the clock converter circuit in FIG. 6. The D flip-flop 407 is negative edge-triggered and has a clock terminal for receiving a clock signal CK1, an imputer terminal for receiving a system reset signal RST, and an output terminal coupled to the reset terminals of the D flip-flops 404 and 405. A system reset signal RST first enters the D flip-flop 407, and is then triggered by the clock signal CK1 and output as a reset signal RSTF to the D flip-flops 404 and 405. Accordingly, it is ensured that the reset signal RSTF is enabled when the clock signal CK1 is at its low status, as shown in FIG. 5.

However, the clock converter circuit provided by the present invention is not limited to the embodiments illustrated in FIG. 4 and FIG. 6. In other embodiments of the present invention, other frequency divider circuits can be adopted for replacing the D flip-flops 404 and 405. The clock converter circuit may include two parallel frequency divider circuits which respectively perform a frequency division operation according to the clock signal CK1 and then output a result X or Y of the frequency division operation. Corresponding to foregoing replacement, the XOR gate 406 may also be replaced by another logic circuit which performs a combinational logic operation according to the signals X and Y to restore the waveform of the clock signal CK1 and provide make sure that the converted signal CK2 has the same waveform, frequency, and phase (or only slightly different) as those of the clock signal CK1.

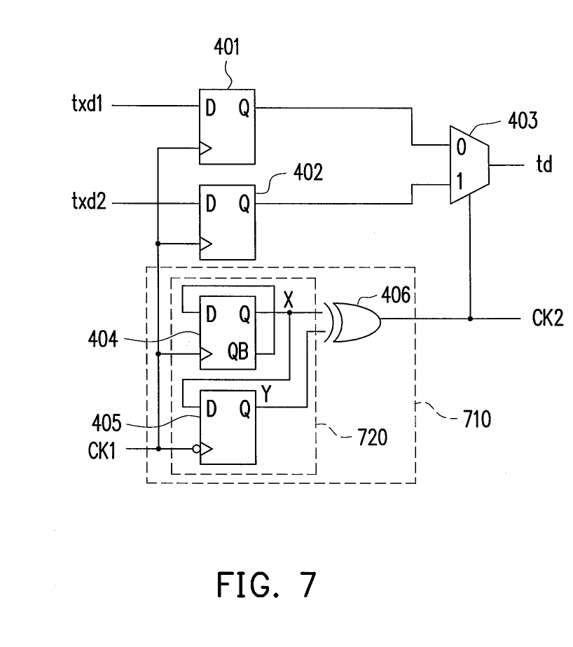

A parallel design is adopted by the logic circuit 420 in FIG. 4, wherein the connections of the D flip-flops 404 and 405 are the same, while a series design is adopted by the logic circuit 720 in FIG. 7. FIG. 7 is a partial circuit diagram of a DDR transmitter according to an embodiment of the present invention, wherein the clock converter circuit 710 includes a logic circuit 720 and an XOR gate 406, and the logic circuit 720 further includes D flip-flops 404 and 405. The circuit illustrated in FIG. 7 is the same as that illustrated in FIG. 4 except the different connections of the D flip-flops 404 and 405.

As shown in FIG. 7, the clock terminals of the D flip-flops 404 and 405 both receive a clock signal CK1, and the non-inverting output terminal thereof are both coupled to the XOR gate 406. The input terminal of the D flip-flop 404 is coupled to the inverting output terminal thereof, and the input terminal of the D flip-flop 405 is coupled to the non-inverting output terminal of the D flip-flop 404. The parallel design in FIG. 4 has to have an external mechanism, such as the additional D flip-flop 407 in FIG. 6, to ensure that the reset signal RSTF is enabled at the right time. However, such an external mechanism is not necessary in the series design as illustrated in FIG. 7, wherein no matter when the reset signal RSTF is enabled, the relationships between the signals CK1, X, Y, and CK2 are always as shown in FIG. 5, so that it is ensured that the signals CK2 and CK1 have the same waveform, frequency, and phase, or only a slight phase difference.

The clock converter circuit with series connection design provided by the present invention is not limited to the embodiment illustrated in FIG. 7; instead, in other embodiments of the present invention, other frequency divider circuits can be used for replacing the D flip-flops 404 and 405. The clock converter circuit may include two frequency divider circuits connected in series. The first frequency divider circuit performs a frequency division operation according to clock signal CK1 and outputs a result X of the frequency division operation. The second frequency divider circuit performs a frequency division operation according to the clock signal CK1 and the signal X and outputs a result Y of the frequency division operation. Corresponding to foregoing replacement, the XOR gate 406 may also be replaced by other type of logic circuit which receives the signals X and Y and performs a combinational logic operation according to the signals X and Y to restore the waveform of the clock signal and provide a converted signal CK2.

The clock converter circuit described in foregoing embodiment is mainly used for converting a clock signal to a general signal so that a timing constraint can be applied thereto easily. As to the method of conversion, the clock signal is used as a trigger signal and passed through a sequential logic circuit, wherein the sequential logic circuit is not limited to a frequency divider circuit. In the embodiment described above, the clock signal enters the clock terminal of a flip-flop, and a sequential logic operation is then performed according to the status of the non-inverting output terminal of the flip-flop. While in another embodiment of the present invention, the sequential logic operation may also be performed according to the status of the inverting output terminal of the flip-flop, and other sequential logic circuit may be used for converting the clock signal. The DDR transmitter in foregoing embodiment may be applied to different fields, such as in a random access memory (RAM), which is so-called DDR RAM. Any DDR transmitter which uses DDR technique and has timing constraint on its clock signal is within the scope of the present invention.

In summary, in the present invention, a sequential logic circuit, such as a flip-flop, is used for converting a clock signal into a general non-clock signal, so that regardless of FPGA or ASIC, a timing constraint can be easily applied to the clock signal and the circuit is not restricted by its position. In addition, the circuit component provided by the present invention is always native simple component regardless in ASIC or FPGA so that a single design thereof is suitable for both ASIC and FPGA. Accordingly, the development and production of DDR transmitter are simplified and the production cost thereof is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A clock converter circuit, comprising:
a first logic circuit, receiving a clock signal as a trigger signal, performing a sequential logic operation according to the clock signal, and outputting a result of the sequential logic operation; and
a second logic circuit, coupled to the first logic circuit, performing a combinational logic operation according to the output of the first logic circuit, and outputting a result of the combinational logic operation as a converted signal, wherein the converted signal and the clock signal have the same waveform and frequency, and the phases of the converted signal and the clock signal are the same or only slightly different, and the phase difference is acceptable as long as the converted signal can be used for replacing the clock signal.

2. The clock converter circuit according to claim 1, wherein the clock signal enters a clock terminal of a flip-flop, and the first logic circuit performs the sequential logic operation according to the status of an output terminal of the flip-flop.

3. The clock converter circuit according to claim 2, wherein the flip-flop is a D flip-flop.

4. The clock converter circuit according to claim 3, wherein the output terminal is the non-inverting output terminal of the flip-flop.

5. The clock converter circuit according to claim 1, wherein the first logic circuit comprises a frequency divider circuit.

6. The clock converter circuit according to claim 1, wherein the first logic circuit comprises:
a first frequency divider circuit, performing a first frequency division operation according to the clock signal, and outputting a result of the first frequency division operation to the second logic circuit; and
a second frequency divider circuit, performing a second frequency division operation according to the clock signal, and outputting a result of the second frequency division operation to the second logic circuit.

7. The clock converter circuit according to claim 6, wherein the first frequency divider circuit comprises a first D flip-flop, and the second frequency divider circuit comprises a second D flip-flop, wherein the first D flip-flop is positive edge-triggered, the second D flip-flop is negative edge-triggered, and each of the first and the second D flip-flop has a clock terminal, an input terminal, a non-inverting output terminal, and a inverting output terminal, wherein the clock terminal receives the clock signal, the input terminal is coupled to the inverting output terminal, and the non-inverting output terminal is coupled to the second logic circuit.

8. The clock converter circuit according to claim 7, wherein the first logic circuit further comprises a third D flip-flop, and the third D flip-flop is negative edge-triggered and has a clock terminal, an input terminal, and an output terminal, wherein the clock terminal receives the clock signal, the input terminal receives a reset signal, and the output terminal is coupled to reset terminals of the first and the second D flip-flop.

9. The clock converter circuit according to claim 1, wherein the first logic circuit comprises:
a first frequency divider circuit, performing a first frequency division operation according to the clock signal, and outputting a result of the first frequency division operation to the second logic circuit; and
a second frequency divider circuit, performing a second frequency division operation according to the clock signal and the result of the first frequency division operation, and outputting a result of the second frequency division operation to the second logic circuit.

10. The clock converter circuit according to claim 9, wherein the first frequency divider circuit comprises a first D flip-flop, and the second frequency divider circuit comprises a second D flip-flop, wherein the first D flip-flop is positive edge-triggered, the second D flip-flop is negative edge-triggered, the clock terminals of the first arid the second D flip-flop both receive the clock signal, the non-inverting output terminals of the first and the second D flip-flop are both coupled to the second logic circuit, the input terminal of the first D flip-flop is coupled to the inverting output terminal of the first D flip-flop, and the input terminal of the second D flip-flop is coupled to the non-inverting output terminal of the first D flip-flop.

11. The clock converter circuit according to claim 1, wherein the second logic circuit comprises a XOR gate.

12. The clock converter circuit according to claim 1, wherein the clock signal is from a clock tree.

13-19. (canceled)
